(19) United States
(12) Patent Application Publication
(10) Pub. No.: US 2026/0178154 A1
(43) Pub. Date: Jun. 25, 2026

(54) TOUCH DISPLAY PANEL AND TOUCH DISPLAY DEVICE

(71) Applicant: Tianma Advanced Display Technology Institute (Xiamen) Co.,Ltd., Xiamen (CN)

(72) Inventors: Wenqi ZHOU, Xiamen (CN); Sitao HUO, Xiamen (CN); Tianyi WU, Xiamen (CN)

(21) Appl. No.: 19/085,513

(22) Filed: Mar. 20, 2025

(30) Foreign Application Priority Data
Dec. 25, 2024 (CN) 202411929918.4

(51) Int. Cl. G06F 3/044; G06F 3/041; H01L 25/075; H10H 29/49; H10H 29/855

(52) U.S. Cl. CPC G06F 3/0443; G06F 3/0412; H10H 29/49; H10H 29/8552; H10W 90/00

(57) ABSTRACT

Touch display panel and touch display device are provided. The touch display panel includes an array substrate, a plurality of LEDs on a side of the array substrate, a first flat layer covering the plurality of LEDs, a shielding layer on a side of the first flat layer away from the array substrate, a first insulating layer on a side of the shielding layer away from the first flat layer, at least one touch electrode layer on a side of the first insulating layer away from the shielding layer, and a protective cover on a side of the at least one touch electrode layer away from the first flat layer.

### CROSS-REFERENCE TO RELATED APPLICATION

This application claims priority of Chinese Patent Application No.: 2024119299184, filed on Dec. 25, 2024, the entire contents of which are hereby incorporated by reference.

### FIELD OF THE DISCLOSURE

The present disclosure generally relates to the field of display technology and, more particularly, relates to a touch display panel and a touch display device.

### BACKGROUND

A Micro-LED display screen has a simple structure and typically includes three major components: a TFT driver, an LED chip and a packaging structure. Compared with LCDs, Micro-LEDs offer advantages such as high brightness, high contrast, wide color gamut and fast response. Compared to OLEDs, Micro-LEDs provide technical benefits, including better reliability and a longer lifespan. Therefore, how to integrate touch functions into Micro-LED display devices has become a research hotspot for a person skilled in the art.

### BRIEF SUMMARY OF THE DISCLOSURE

One aspect of the present disclosure provides a touch display panel. The touch display panel includes an array substrate, a plurality of LEDs on a side of the array substrate, a first flat layer covering the plurality of LEDs, a shielding layer on a side of the first flat layer away from the array substrate, a first insulating layer on a side of the shielding layer away from the first flat layer, at least one touch electrode layer on a side of the first insulating layer away from the shielding layer, and a protective cover on a side of the at least one touch electrode layer away from the first flat layer.

Another aspect of the present disclosure provides a touch display device including a touch display panel. The touch display panel includes an array substrate, a plurality of LEDs on a side of the array substrate, a first flat layer covering the plurality of LEDs, a shielding layer on a side of the first flat layer away from the array substrate, a first insulating layer on a side of the shielding layer away from the first flat layer, at least one touch electrode layer on a side of the first insulating layer away from the shielding layer, and a protective cover on a side of the at least one touch electrode layer away from the first flat layer.

Other aspects of the present disclosure can be understood by a person skilled in the art in light of the description, the claims, and accompanying drawings of the present disclosure.

### BRIEF DESCRIPTION OF THE DRAWINGS

The above and other features, advantages, and aspects of various embodiments of the present disclosure will become more apparent with reference to the following detailed description, taken in conjunction with the accompanying drawings. Throughout the accompanying drawings, same or similar reference numbers refer to same or similar elements. It is to be understood that the accompanying drawings are schematic, components and elements are not necessarily drawn to scale.

FIG. 1 illustrates a schematic diagram of a touch display panel provided by one embodiment of the present disclosure;

FIG. 2 illustrates a schematic diagram of a touch display panel provided by another embodiment of the present disclosure;

FIG. 3 illustrates a schematic diagram of a touch display panel provided by another embodiment of the present disclosure;

FIG. 4 illustrates a schematic diagram of a touch display panel provided by another embodiment of the present disclosure;

FIG. 5 illustrates a schematic diagram of a touch display panel provided by another embodiment of the present disclosure;

FIG. 6 illustrates a schematic diagram of a touch display panel provided by another embodiment of the present disclosure;

FIG. 7 illustrates a schematic diagram of a touch display panel provided by another embodiment of the present disclosure;

FIG. 8 illustrates a top view of a shielding layer, a first touch electrode layer and a third touch electrode layer in a touch display panel provided by one embodiment of the present disclosure;

FIG. 9 illustrates a top view of a shielding layer, and a first touch electrode layer in a touch display panel provided by one embodiment of the present disclosure;

FIG. 10 illustrates a schematic diagram of a touch display panel provided by another embodiment of the present disclosure;

FIG. 11 illustrates a top view of a shielding layer, and a second touch electrode layer in a touch display panel provided by one embodiment of the present disclosure;

FIG. 12 illustrates a schematic diagram of a touch display panel provided by another embodiment of the present disclosure;

FIG. 13 illustrates a schematic diagram of a touch display panel provided by another embodiment of the present disclosure;

FIG. 14 illustrates a top view of an electrical connection location between a ground electrode and a shielding layer in a touch display panel provided by one embodiment of the present disclosure;

FIG. 15 illustrates a schematic diagram of a touch display panel provided by another embodiment of the present disclosure;

FIG. 16 illustrates a top view of an electrical connection location between a ground electrode and a shielding layer in a touch display panel provided by one embodiment of the present disclosure;

FIG. 17 illustrates a schematic diagram of a touch display panel provided by another embodiment of the present disclosure;

FIG. 18 illustrates a schematic diagram of a touch display panel provided by another embodiment of the present disclosure;

FIG. 19 illustrates a schematic diagram of a touch display panel provided by another embodiment of the present disclosure;

FIG. 20 illustrates a schematic diagram of a touch display panel provided by another embodiment of the present disclosure;

FIG. 21 illustrates a schematic diagram of a touch display panel provided by another embodiment of the present disclosure;

FIG. 22 illustrates a schematic diagram of a touch display panel provided by another embodiment of the present disclosure;

FIG. 23 illustrates a schematic diagram of a touch display panel provided by another embodiment of the present disclosure;

FIG. 24 illustrates a schematic diagram of a touch display panel provided by another embodiment of the present disclosure;

FIG. 25 illustrates a top view of a touch display panel provided by one embodiment of the present disclosure;

FIG. 26 illustrates a schematic diagram of a touch display panel provided by another embodiment of the present disclosure;

FIG. 27 illustrates a top view of a touch display panel provided by another embodiment of the present disclosure;

FIG. 28 illustrates a top view of a touch display panel provided by another embodiment of the present disclosure;

FIG. 29 illustrates a flow chart of forming a touch display panel provided by one embodiment of the present disclosure;

FIG. 30 illustrates a top view of a touch display panel provided by another embodiment of the present disclosure;

FIG. 31 illustrates a schematic diagram of a touch display panel provided by another embodiment of the present disclosure;

FIG. 32 illustrates a schematic diagram of a touch display panel provided by another embodiment of the present disclosure;

FIG. 33 illustrates a schematic diagram of a touch display panel provided by another embodiment of the present disclosure;

FIG. 34 illustrates a schematic diagram of a touch display panel provided by another embodiment of the present disclosure;

FIG. 35 illustrates a schematic diagram of a touch display panel provided by another embodiment of the present disclosure;

FIG. 36 illustrates a schematic diagram of a touch display panel provided by another embodiment of the present disclosure; and

FIG. 37 illustrates a schematic diagram of a touch display device provided by one embodiment of the present disclosure.

### DETAILED DESCRIPTION

Technical solutions in the embodiments of the present disclosure will be clearly and completely described below with reference to the embodiments of the present disclosure. Obviously, the embodiments described herein represent only a portion, not all, of the embodiments of the present disclosure. Any other embodiments derived by a person skilled in the art without creative efforts fall within the protection scope of the present disclosure.

It will be apparent to a person skilled in the art that various modifications and changes can be made in the present disclosure without departing from the spirit or scope of the present disclosure. Therefore, the present disclosure is intended to cover modifications and variations of the present disclosure that fall within the scope of the corresponding claims (claimed technical solutions) and equivalents thereof. It should be noted that implementation methods in the embodiments of the present disclosure can be combined with each other without conflict.

To make the above objectives, features and advantages of the present disclosure more apparent and understandable, the present disclosure will be described in further detail below in conjunction with the accompanying drawings and specific implementation modes.

As mentioned in the background section, how to integrate touch functions in Micro-LED display devices has become a research hotspot for a person skilled in the art.

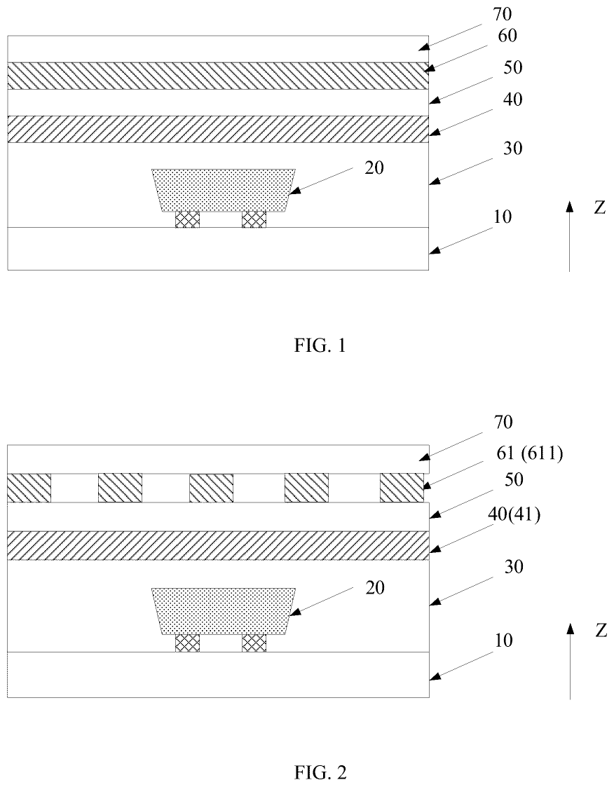

In one embodiment, a touch display panel is provided. As shown in FIG. 1, the touch display panel includes an array substrate 10; a plurality of LEDs 20 on a side of the array substrate 10; a first flat layer 30 covering the plurality of LEDs 20; a shielding layer 40 on a side of the first flat layer 20 away from the array substrate 10; a first insulating layer 50 on a side of the shielding layer 40 away from the first flat layer 30; at least one touch electrode layer 60 on a side of the first insulating layer 50 away from the shielding layer 40; and a protective cover 70 on a side of the at least one touch electrode layer 60 away from the first flat layer 30.

Optionally, in one embodiment, the LED may be a Micro-LED or a Mini-LED, which is not limited herein.

Specifically, in one embodiment, the at least one touch electrode layer 60 and the shielding layer 40 are made of a transparent material such as ITO, so that the at least one touch electrode layer 60 and the shielding layer 40 can transmit light emitted by the LED 20 to ensure a display of the touch display panel's screen.

The touch display panel includes a plurality of LEDs 20 for display and at least one touch electrode layer 60 for touch control, so that a touch function is integrated into the LED display panel.

Moreover, in the touch display panel, the at least one touch electrode layer 60 is located between the protective cover 70 and the shielding layer 40, that is, the at least one touch electrode layer 60 is integrated into the touch display panel, thereby reducing a thickness of the touch display panel while incorporating the touch function into the LED display panel, which is conducive to a development of a lightweight and slim touch display panel.

In addition, in the touch display panel, a shielding layer 40 is arranged between the at least one touch electrode layer 60 and the plurality of LEDs 20, so that the shielding layer 40 can be used to shield an interference from a driving signal of the LED 20 on the at least one touch electrode layer 60, thereby improving a touch detection accuracy of the touch display panel.

Optionally, in one embodiment, as shown in FIG. 2, the shielding layer 40 includes a plurality of first electrodes 41. The at least one touch electrode layer 60 includes a first touch electrode layer 61, which includes a plurality of second electrodes 611. The first electrodes 41 are driving electrodes, and the second electrodes 611 are sensing electrodes, thereby utilizing capacitances between the first electrodes 41 and the second electrodes 611 to achieve touch detection.

It should be noted that, in the embodiment, the plurality of first electrodes 41 included in the shielding layer 40 are driving electrodes. When the touch display panel performs touch detection, a driving signal is input to the first electrodes 41 and a sensing signal is output to the second electrode 611. Therefore, during a touch detection process, a voltage signal on the first electrode 41 is a constant voltage signal, which is less affected by the driving signal of the LED 20. As a result, in the touch display panel, the driving electrodes can be reused as a shielding layer, thereby reducing interference from the LED 20 driving signals with touch detection, improving touch detection accuracy, and at a same time, reducing a thickness of the touch display panel, which is suitable for a development of a lightweight and slim touch display panel.

In the touch display panel, in a process of realizing touch detection by utilizing capacitance changes between the driving electrodes and the sensing electrodes. To improve the touch detection accuracy, the driving electrodes are arranged at a high density. Therefore, the driving electrodes (that is, the first electrodes 41) are located between the second electrodes (i.e., the sensing electrodes 611) and the LED 20, which also helps reduce interference from the driving signals of the LED 20 on the second electrodes 611 in the first touch electrode layer 61.

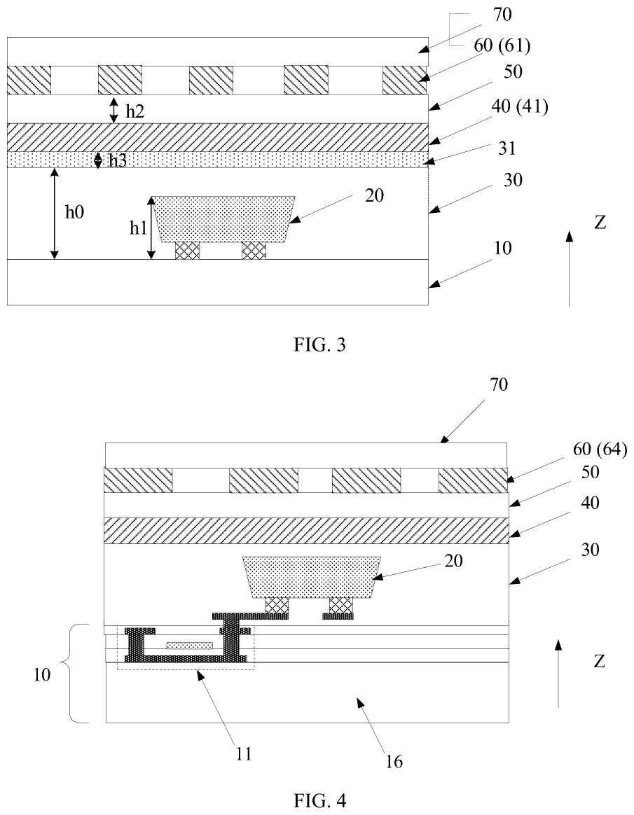

Based on the above embodiment, in one embodiment, the first insulating layer 50 is an insulating substrate. Optionally, the insulating substrate 50 can be a touch function film. As shown in FIG. 3, the shielding layer 40 and the first flat layer 30 are bonded through a first adhesive layer 31. Optionally, the first adhesive layer 31 may be an optically transparent adhesive layer, so that the first adhesive layer 31 adheres to both the shielding layer 40 and the first flat layer 30 without affecting a light emission of the LED.

In the above embodiment, since the first insulating layer 50 is an insulating substrate, the insulating substrate has a certain hardness and can provide sufficient supporting strength to the first electrodes 41 and the second electrodes 611. Therefore, in one embodiment, when the touch display panel is formed, the first electrodes 41 and the second electrodes 611 can be formed on opposite sides of the insulating substrate. For example, the first electrodes 41 are formed on one side of the insulating substrate, and the second electrodes 611 are formed on the other side of the insulating substrate. The side of the insulating substrate with the first electrodes 41 is bonded to the first flat layer 30 at least through the first adhesive layer 31.

In the above embodiment, the first electrodes 41 and the second electrodes 611 are formed on the insulating substrate and bonded to the first flat layer 30. During subsequent use of the touch display panel, if an issue arises with the first electrodes 41 and/or the second electrodes 611, it is only necessary to separate the insulating structure from the first flat layer 30 and replace the insulating substrate along with electrodes on a surface thereof without scrapping the entire touch display panel, which reduces a maintenance cost of the touch display panel.

Optionally, based on the above embodiment, in one embodiment, the first electrodes 41 and the second electrodes 611 are metal electrodes. Furthermore, the first electrodes 41 and the second electrodes 611 are active metal electrodes, which reduce resistances thereof and improve signal transmission efficiency thereof. Specifically, in one embodiment, the first electrodes 41 and the second electrodes 611 are copper electrodes.

Metals are easily oxidized in a water-oxygen environment, especially active metals are more easily oxidized in a water-oxygen environment. Therefore, in the above embodiment, after the first electrodes 41 and the second electrodes 611 are formed on the insulating substrate and before the first electrodes 41 and the second electrodes 611 are attached to the first flat layer 30, the first electrodes 41 and the second electrodes 611 are easily oxidized, thereby affecting conductive properties of the first electrodes 41 and the second electrodes 611, and even affecting service lives of the first electrodes 41 and the second electrodes 611.

Therefore, based on the above embodiments, in one embodiment, the first electrodes 41 are covered with a first protective layer on a side away from the first insulating layer 50, and the second electrodes 611 are covered with a second protective layer away from the first insulating layer 50, which helps reduce a probability probability of oxidation of the first electrodes and the second electrodes from water and oxygen in an environment after the first electrodes and the second electrodes are formed. Optionally, the first protective layer and the second protective layer are transparent, which do not affect a light emission of the LED 20 while protecting of the first electrodes 41 and the second electrodes 611. Specifically, the first protective layer and the second protective layer may be made of acrylic resin or epoxy resin, which are not limited herein.

In other embodiments, the first electrodes 41 and the second electrodes 611 may also be made of inactive metals, such as molybdenum or titanium. Since the inactive metals are not easily oxidized, if the first electrodes 41 and the second electrodes 611 are made of inactive metal, the first protective layer and the second protective layer may not need to be formed in the touch display panel.

In one embodiment, as shown in FIG. 3, a thickness h0 of the first flat layer 30 is greater than a thickness h2 of the first insulating layer 50, ensuring that the first flat layer 30 provides a flattening effect. At a same time, the thinner first insulating layer 50 helps reduce an overall thickness of the touch display panel, which is suitable for a development of a lightweight and slim touch display panel.

In one embodiment, as shown in FIG. 3, the thickness h0 of the first flat layer 30 is greater than a thickness h3 of the first adhesive layer 31, ensuring that the first flat layer 30 provides a flattening effect. At a same time, the thinner first adhesive layer 31 helps reduce an overall thickness of the touch display panel, which is suitable for a development of a lightweight and slim touch display panel.

In another embodiment, as shown in FIG. 3, the thickness h0 of the first flat layer 30 is greater than the thickness h2 of the first insulating layer 50, ensuring that the first flat layer 30 provides a flattening effect. At a same time, the thinner first insulating layer 50 and the first adhesive layer 31 help reduce an overall thickness of the touch display panel, which is suitable for a development of a lightweight and slim touch display panel.

Specifically, in one embodiment, the thickness of the first flat layer 30 ranges from 5 μm to 30 μm, the thickness of the first insulating layer 50 ranges from 0.03 mm to 0.15 mm, and the thickness of the first adhesive layer 31 ranges from 0.05 mm to 0.15 mm, which is not limited herein.

Specifically, in one embodiment, a thickness of the array substrate 10 is 0.5 mm, the thickness of the first flat layer 30 is 0.015 mm, the thickness of the first adhesive layer 31 is 0.1 mm, the thickness of the first insulating layer 50 is 0.06 mm. In the touch display panel, an overall thickness from the array substrate to the at least one touch electrode layer 60 is 0.78 mm, which is not limited herein. In one embodiment, as shown in FIG. 4, the array substrate 10 includes a base substrate 16 and a pixel circuit 11 and other structures located between the base substrate 16 and the LED 20. Since a thickness of the base substrate 16 in the array substrate 10 is relatively large in a direction Z perpendicular to the plane where the touch display panel is located, while a thickness of the pixel circuit 11 and other structures between the base substrate 16 and the LED 20 is relatively small (only a few microns). Therefore, in one embodiment, the thickness of the array substrate 10 may be the thickness of the base substrate 16 or may be an overall thickness of the base substrate 16 and the pixel circuit 11 and other structures in the array substrate 10, which is not limited herein.

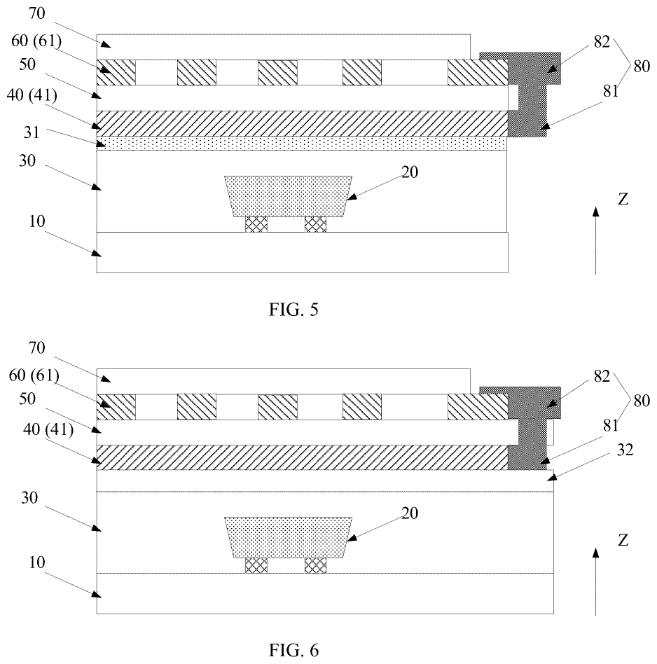

Based on any of the above embodiments, in one embodiment, as shown in FIG. 5, the touch display panel further includes a touch circuit 80. The touch circuit 80 includes a first touch circuit 81 bonded to a side of the first insulating layer 50 facing the first flat layer 30, and a second touch circuit 82 bonded to a side of the first insulating layer 50 facing the protective cover 70. Optionally, in one embodiment, when the first insulating layer 50 is an insulating substrate, the first touch circuit 81, which provides a driving signal to the driving electrode, is bonded to a side of the insulating substrate where the shielding layer is formed. The second touch circuit 82, which detects a signal from a sensing electrode, is bonded to a side of the insulating substrate where the first touch electrode layer 61 is formed.

Optionally, in one embodiment, the touch display panel includes a flexible circuit board (FPC) arranged on a side of the insulating substrate where the first touch electrode layer 61 is formed. The second touch circuit 82 is arranged on the flexible circuit board, while the first touch circuit 81 is electrically connected to a signal source on the flexible circuit board that outputs a driving signal. That is, in the embodiment, the first touch circuit 81 and the second touch circuit 82 are bonded to a circuit board (i.e., FPC, flexible circuit board) through two bindings.

In another embodiment, as shown in FIG. 6, the first insulating layer 50 is a flat layer, and a second flat layer 32 is further arranged between the shielding layer 40 and the first flat layer 30. When forming the touch display panel, after the first flat layer 30 is formed, a second flat layer 32 is formed on a surface of the first flat layer 30. After the second flat layer 32 is formed, the shielding layer 40 is formed on a surface of the second flat layer 32. After the shielding layer 40 is formed, a first insulating layer 50 is formed on a surface of the shielding layer 40. After the first insulating layer 50 is formed, a first touch electrode layer 61 is formed on a surface of the first insulating layer 50.

Since the adhesive layer has a certain degree of flexibility, if the shielding layer 40 and/or the first touch electrode layer 61 are formed on the flexible adhesive layer, collapse may occur. Therefore, in one embodiment, when the shielding layer 40 and the first touch electrode layer 61 are sequentially formed on a side of the first flat layer 30 away from the array substrate 10, a second flat layer 32 needs to be formed on a side of the first flat layer 30 away from the array substrate 10 to provide a flat surface for forming the shielding layer 40 and offer supporting strength for the shielding layer 40, thereby reducing a probability of collapse of the shielding layer 40 after the shielding layer 40 is formed. Similarly, the first insulating layer 50 is a flat layer, which can not only provide a flat surface for producing the first touch electrode layer 61 but also can offer certain supporting strength for the first touch electrode layer 61, reducing a probability of collapse of the first touch electrode layer 61 after the first touch electrode layer 61 is formed.

Based on the above embodiments, in one embodiment, as shown in FIG. 6, the touch display panel further includes a touch circuit 80. The touch circuit 80 includes a first touch circuit 81 bonded to a side of the first insulating layer 50 facing the first flat layer 30 and a second touch circuit 82 bonded to a side of the first insulating layer 50 facing the protective cover 70. Optionally, in one embodiment, in a plane parallel to the touch display panel, an area of the second flat layer 32 is larger than an area of the shielding layer 40, to facilitate a binding of the first touch circuit 81 between the second flat layer 32 and the shielding layer 40. Similarly, in the plane parallel to the touch display panel, an area of the first insulating layer 50 is larger than an area of the first touch electrode layer 61 to facilitate a binding of the second touch circuit 82 between the first insulating layer 50 and the first touch electrode layer 61.

When the first insulating layer 50 is a flat layer, the second flat layer 32, the shielding layer 40, the first insulating layer 50, and the first touch electrode layer 61 are formed sequentially in a series of processes without involving a transfer and binding process, which minimizes a probability of oxidation. Therefore, based on the above embodiment, in one embodiment, the first electrodes 41 and the second electrodes 611 may be active metals or inactive metals, and surfaces of the first electrodes 41 and the second electrodes 611 may or may not be covered with a protective layer, which is not limited herein.

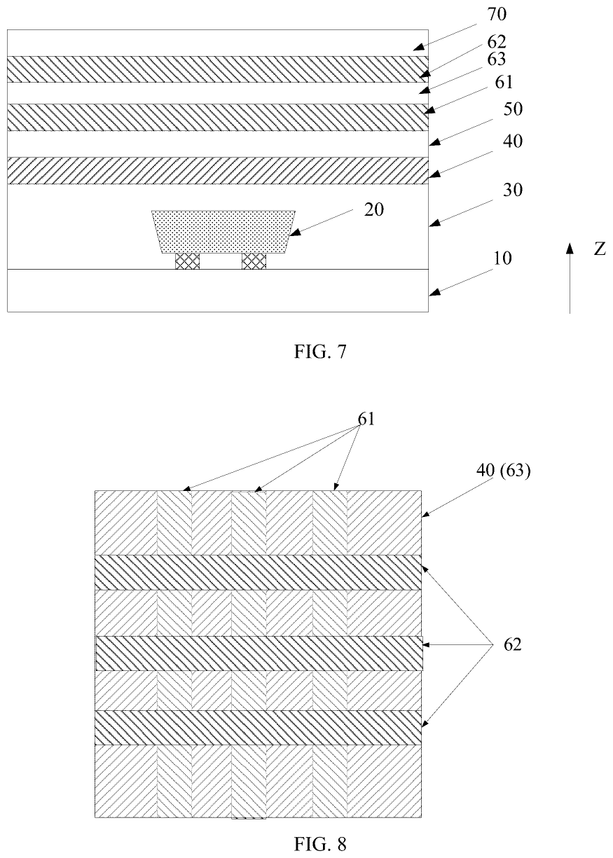

In other embodiments, the shielding layer may not be reused as driving electrodes. In one embodiment, as shown in FIG. 7, the at least one touch electrode layer includes a first touch electrode layer 61 and a third touch electrode layer 62. An interlayer second insulating layer 63 is provided between the first touch electrode layer and the third touch electrode layer. The first touch electrode layer 61 includes a plurality of second electrodes, and the third touch electrode layer 62 includes a plurality of third electrodes. Capacitance changes between the second electrodes and the third electrodes are used for touch detection.

Optionally, in one embodiment, the second electrodes are driving electrodes, and the third electrodes are sensing electrodes. In another embodiment, the second electrodes are sensing electrodes, and the third electrodes are driving electrodes, which are not limited herein.

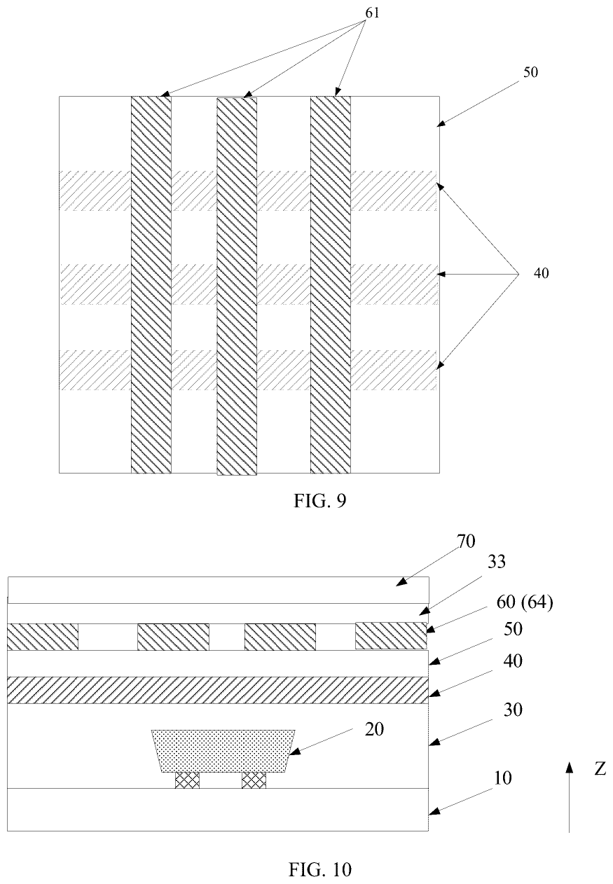

When the shielding layer 40 is not reused as a touch electrode, the shielding layer 40 can be a whole layer to enhance a shielding performance of the shielding layer on an LED 20 signal. As shown in FIGS. 8 and 9, FIG. 8 illustrates a top view of the shielding layer 40, the first touch electrode layer 61 and the third touch electrode layer 62 when the shielding layer 40 is not reused as a touch electrode. FIG. 9 illustrates a top view of the shielding layer 40 and the first touch electrode layer 61 when the shielding layer 40 is reused as a touch electrode.

In the embodiment, since a shielding layer is arranged between the first touch electrode layer 61 and the LED 20, even if the second electrodes in the first touch electrode layer 61 can function as sensing electrodes without being affected by an LED driving signal.

Optionally, in the direction Z perpendicular to the plane of the touch display panel, the shielding layer 40 at least covers a wiring electrically connected to a plurality of LEDs 20 but is not limited thereto.

The above embodiments describe the touch display panel using mutual capacitance as a touch detection principle. In other embodiments, the touch display panel can also implement touch detection based on self-capacitance. The following section describes a structure of the touch display panel when using self-capacitance for touch detection.

As shown in FIGS. 10 and 11, FIG. 11 illustrates a top view of the shielding layer and the second touch electrode layer in FIG. 10. In one embodiment, the at least one touch electrode layer 60 includes a second touch electrode layer, and the second touch electrode layer includes a plurality of block electrodes 64. In the direction Z perpendicular to the plane of the touch display panel, the shielding layer 40 overlaps a plurality of block electrodes 64. Optionally, in the direction Z perpendicular to the plane of the touch display panel, the shielding layer 40 covers the plurality of block electrodes 64 to reduce interference from driving signals from the LED 20 on detection signals from the plurality of block electrodes 64, thereby enhancing touch detection accuracy.

Optionally, in one embodiment, a third flat layer 33 is further arranged between the at least one touch electrode layer 60 and the protective cover 70 to serve as a protective layer for the at least one touch electrode layer 60.

Specifically, in one embodiment, a thickness of the second touch electrode layer is less than 1 μm, and a thickness of the third flat layer 33 ranges from 1 μm to 10 μm, which is not limited herein.

Optionally, in a specific embodiment, the thickness of the array substrate 10 is 0.5 mm, the thickness of the first flat layer 30 is 0.015 mm, the thickness of the first insulating layer 50 is 0.015 mm, the thickness of the second touch electrode layer is less than 1 μm, and the thickness of the third flat layer 33 is 0.03 mm. In the touch display panel, the overall thickness from the array substrate 10 to the at least one touch electrode layer 60 is 0.64 mm, which is not limited herein.

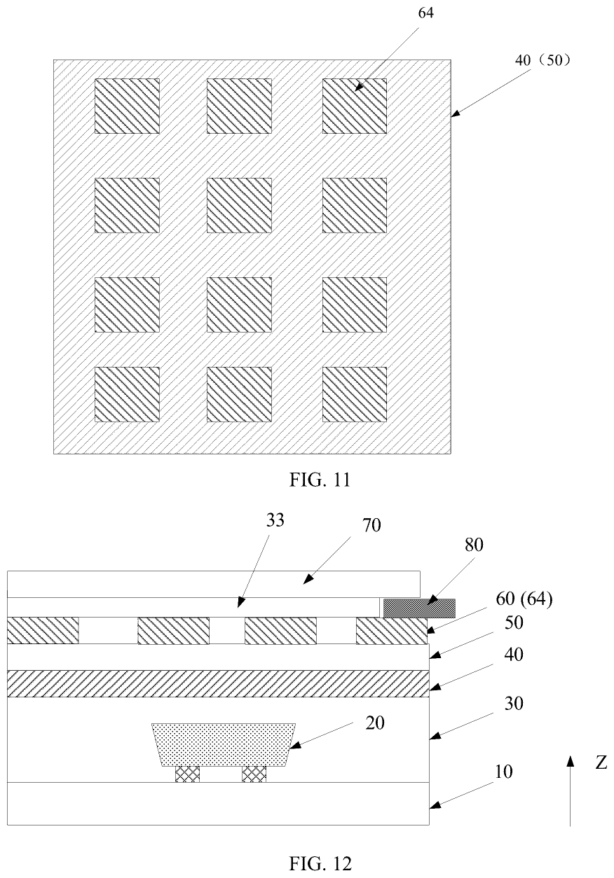

Based on the above embodiments, in one embodiment, as shown in FIG. 12, the touch display panel includes a touch circuit 80 bonded to a side of the first insulating layer 50 facing the protective cover 70.

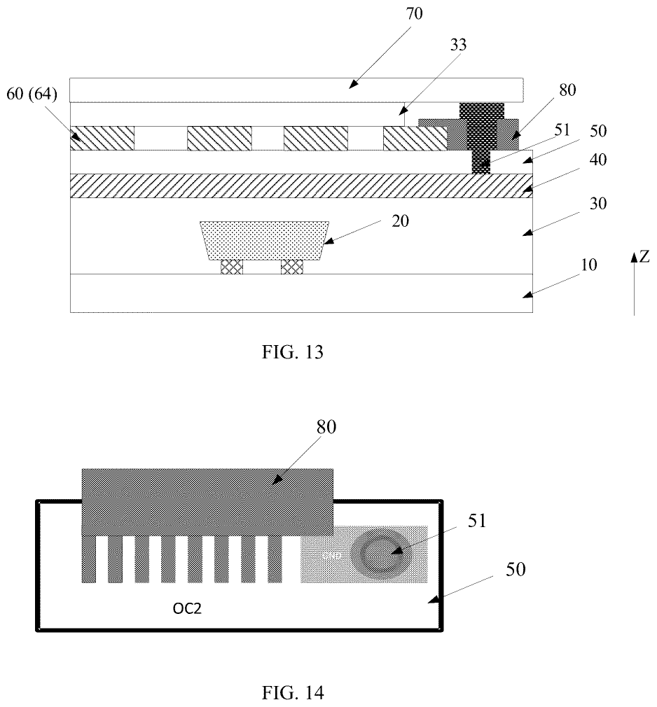

Optionally, based on the above embodiment, in one embodiment, as shown in FIGS. 13-16, the first insulating layer 50 includes a through hole 51. The shielding layer 40 is electrically connected to a ground electrode in the touch circuit 80 through the through hole 51 to ensure a fixed zero potential to the shielding layer 40, which minimizes voltage fluctuations on the shielding layer 40, thereby enhancing a shielding effectiveness of the shielding layer 40. The touch circuit 80 also includes a plurality of other signal pins, which are well known to a person skilled in the art and will not be described in detail herein.

Optionally, in one embodiment, the through hole 51 is filled with silver glue, that is, the ground electrode in the touch circuit 80 is electrically connected to the shielding layer 40 by dispensing silver glue into the through hole 51. During a specific formation, the through hole 51 is formed in the first insulating layer 50 to expose the shielding layer 40. The touch circuit 80 is bonded to the first insulating layer 50. Silver glue is applied to the through hole 51 to electrically connect the ground electrode in the touch circuit 80 to the shielding layer 40. The touch circuit 80 and the silver glue are insulated and sealed together.

Specifically, in one embodiment, as shown in FIGS. 13 and 14, in the direction Z perpendicular to the plane of the touch display panel, the ground electrode covers the through hole 51 to enhance electrical contact performance between the ground electrode and the shielding layer 40. However, due to space requirements of a dispensing process, the ground electrode covering the through hole 51 is suitable for application scenarios with sufficient frame space, preventing short circuits between a conductor in the through hole and other signal pins near the ground electrode.

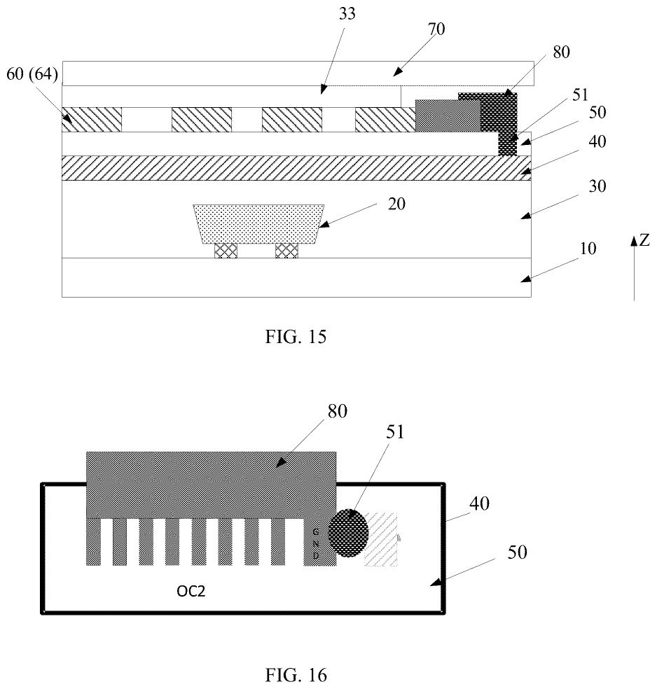

In another embodiment, as shown in FIGS. 15 and 16, in the direction Z perpendicular to the plane of the touch display panel, the through hole 51 is located on a side of the ground electrode away from the touch electrode of the touch display panel, so that the conductor in the through hole 51 is farther from other signal pins inside the ground electrode, thereby reducing frame space requirements.

Based on any of the above embodiments, in one embodiment, as shown in FIG. 3, a height of the first flat layer 30 is not lower than a height of the LED 20. That is, a surface of the first flat layer 30 on a side away from the array substrate 10 is not lower than a surface on a side of the LED 20 away from the array substrate 10, thereby providing a flat surface to produce the shielding layer 40 and facilitating a formation of the shielding layer 40. Optionally, in one embodiment, in the direction Z perpendicular to the plane of the touch display panel, the thickness h0 of the first flat layer 30 and a thickness h1 of the LED 20 satisfy the following relationship: h1≤h0≤2*h1, to provide a flat surface for forming the shielding layer 40, thereby preventing the first flat layer 30 from being excessively thick, which would increase processing difficulty.

Based on any of the above embodiments, in one embodiment, the touch display panel further includes an anti-reflection structure between the array substrate and the protective cover to reduce ambient light reflection on a display surface of the touch display panel and improve display quality of the touch display panel.

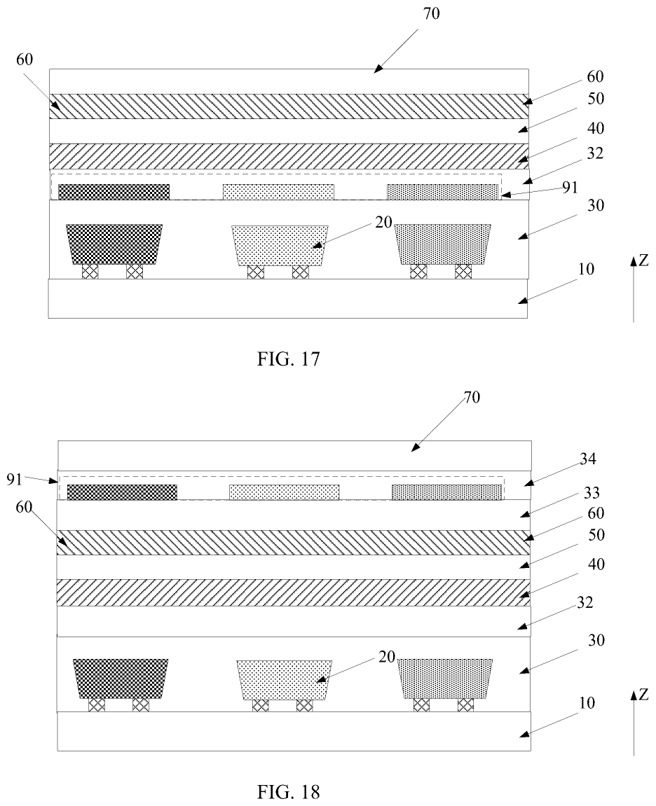

Optionally, in one embodiment, as shown in FIG. 17, the anti-reflection structure includes a first anti-reflection structure 91 between the LED 20 and the protective cover 70. Specifically, the first anti-reflection structure 91 includes a plurality of color resistance units. The plurality of color resistance units covers the plurality of LEDs 20 in the direction Z perpendicular to the plane of the array substrate. The plurality of color resistance units is used to reduce ambient light reflection on the display surface of the touch display panel, such as on a light exit area of the touch display panel, thereby improving display quality of the touch display panel without affecting light emission from each LED.

Specifically, in one embodiment, as shown in FIG. 17, a second flat layer 32 is arranged between the shielding layer 40 and the first flat layer 30. The plurality of color resistance units is arranged on a side surface of the first flat layer 30 away from the array substrate 10. The second flat layer 32 covers the plurality of color resistance units. The shielding layer 40 is on a side of the second flat layer 32 away from the array substrate 10. Optionally, in one embodiment, the thickness of the second flat layer ranges from 1 μm to 10 μm, which is not limited herein.

In another embodiment, as shown in FIG. 18, a third flat layer 33 and a fourth flat layer 44 are arranged between the at least one touch electrode layer 60 and the protective cover 70. The third flat layer 33 is located on a side surface of the at least one touch electrode layer 60, away from the array substrate 10. The plurality of color resistance units is located on a side surface of the third flat layer 33, away from the at least one touch electrode layer 30. The fourth flat layer 34 covers the plurality of color resistance units. The protective cover 70 is located on a side surface of the fourth flat layer 34, away from the array substrate 10.

In the above embodiment, the closer the first anti-reflection structure 91 is to the protective cover 70, the better the effect thereof on reducing ambient light reflection on the display surface of the touch display panel and improving display quality of the touch display panel. However, the larger the area required for each color resistance unit to cover the light emitted by a corresponding LED 20 and the closer the first anti-reflection structure 91 is to the LED 20, the smaller an area required for each color resistance unit to fully cover light emitted by the corresponding LED 20. In other embodiments, the plurality of color resistance units can also be located at other locations in the touch display panel as long as the plurality of color resistance units is located between the LED 20 and the protective cover 70, which can reduce ambient light reflection on the display surface of the touch display panel, improve display quality of the touch display panel without affecting light emission from each LED.

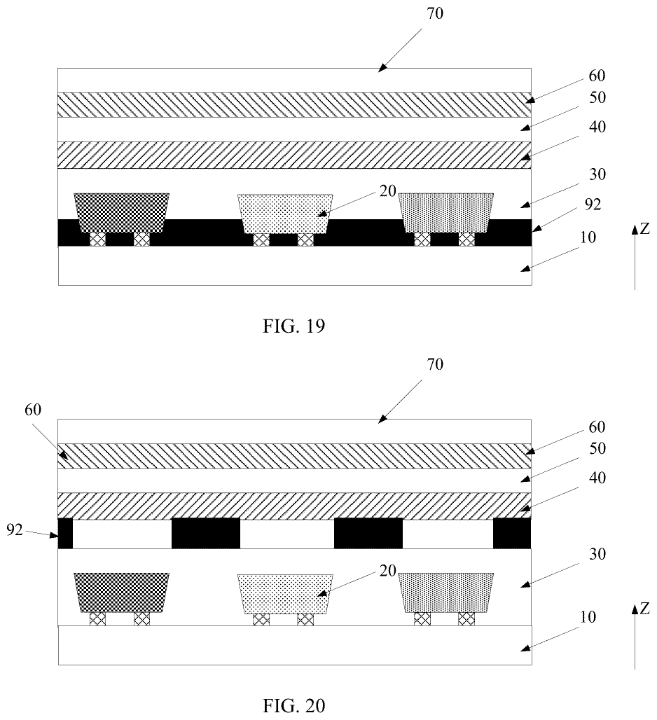

Based on any of the above embodiments, in one embodiment, as shown in FIG. 19, the anti-reflection structure includes a second anti-reflection structure 92 with light-absorbing layers. At least part of the light-absorbing layers is located in regions between adjacent LEDs 20 to reduce ambient light reflection from a display surface of the touch display panel, such as a non-light exit area of the touch display panel, thereby improving display quality of the touch display panel. Optionally, the light-absorbing layers may be black light-absorbing layers.

Optionally, based on the above embodiment, in one embodiment, as shown in FIG. 19, the second anti-reflection structure 92 and the LEDs 20 are on a same layer. In one embodiment, the second anti-reflection structure 92 is located not only in gaps between adjacent LEDs 20 but also in gaps between the LEDs 20 and the array substrate 10, which maximizes an area of the second anti-reflection structure 92, improve an effectiveness of the second anti-reflection structure 92 in reducing ambient light reflection on the display surface of the touch display panel, and reduce the crosstalk between the light of adjacent LEDs.

In another embodiment, as shown in FIG. 20, the second anti-reflection structure 92 is located between the first flat layer 30 and the shielding layer 40. In the direction Z parallel to the plane of the touch display panel, the second anti-reflection structure 92 is located only in gaps between adjacent LEDs 20, to use the second anti-reflection structure 92 to reduce ambient light reflection on the display surface of the touch display panel without affecting the light emission of the LEDs 20.

In other embodiments, the second anti-reflection structure 92 can also be located at other locations between the array substrate 10 and the protective cover 70, as long as the second anti-reflection structure 92 can reduce ambient light reflection on the display surface of the touch display panel without affecting the light emission of the LEDs.

If the second anti-reflection structure 92 and the LED 20 are located on a same layer, during a forming process of the touch display panel, if the second anti-reflection structure 92 is formed first and an LED 20 is transferred afterward, an opening in the second anti-reflection structure 92 should be larger to facilitate the alignment and transfer of the LED 20. Specifically, in the direction Z parallel to the plane of the touch display panel, the opening area of the second anti-reflection structure 92 is larger than the area of a corresponding LED. Side edges of the second anti-reflection structure 92 cannot be aligned with side edges of the LED 20. If the second anti-reflection structure 92 is located on a side of the LED 20 away from the array substrate 10, the second anti-reflection structure 92 is formed after the alignment and transfer of the LED 20. Therefore, when the second anti-reflection structure 92 is formed, in the direction Z perpendicular to the plane of the touch display panel, side bondedaries of the second anti-reflection structure 92 can align with side bondedaries of the LED 20 to maximize an area of the second anti-reflection structure 92.

Compared to a surface of the array substrate 10, a surface of the first flat layer 30 is relatively flat. Therefore, the second anti-reflection structure 92 is located between the first flat layer 30 and the shielding layer 40, which can also reduce processing difficulty of the second anti-reflection structure 92.

In other embodiments, the anti-reflection structure may also include at least two layers of second anti-reflection structures 92 to further reduce ambient light reflection on the display surface of the touch display panel by arranging the second anti-reflection structures 92 on different layers of the touch display panel. In the direction Z perpendicular to the plane of the touch display panel, the second anti-reflection structure 92 located on a side of the LED 20 away from the array substrate 10 does not overlap a light emission area of the LED 20, so that the arrangement of the second anti-reflection structure 92 does not affect light emission of the LED 20.

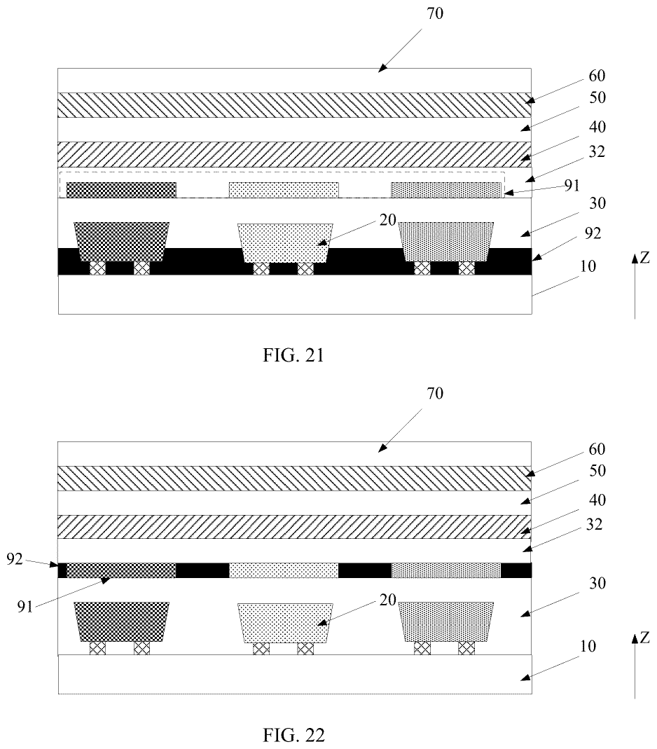

In another embodiment, as shown in FIG. 21, the anti-reflection structure includes a first anti-reflection structure 91 and a second anti-reflection structure 92 configured for simultaneously reducing ambient light reflection on the display surface of the touch display panel, thereby further improving quality of the display surface of the touch display panel.

Optionally, in one embodiment, the first anti-reflection structure 91 and the second anti-reflection structure 92 can be located on different layers, as shown in FIG. 21, or on a same layer, as shown in FIG. 22, which is not limited herein.

When the first anti-reflection structure 91 and the second anti-reflection structure 92 are located on a same layer, in the direction Z perpendicular to the plane of the touch display panel, an anti-reflection structure formed by the first anti-reflection structure 91 and the second anti-reflection structure 92 can completely cover a display area of the touch display panel, thereby minimizing ambient light reflection on the display surface of the touch display panel and improving quality of a display screen of the touch display panel.

Specifically, in one embodiment, as shown in FIG. 22, when the first anti-reflection structure 91 and the second anti-reflection structure 92 are located on a same layer, the first anti-reflection structure 91 and the second anti-reflection structure 92 are located between the first flat layer 30 and the shielding layer 40, which is not limited herein. In the direction Z perpendicular to the plane of the array substrate, a color resistance unit covers a corresponding LED 20, to reduce ambient light reflection on the display surface of the touch display panel and improve quality of a display screen of the touch display panel without affecting light emission of the LED by using the anti-reflection structure formed by the first anti-reflection structure 91 and the second anti-reflection structure 92.

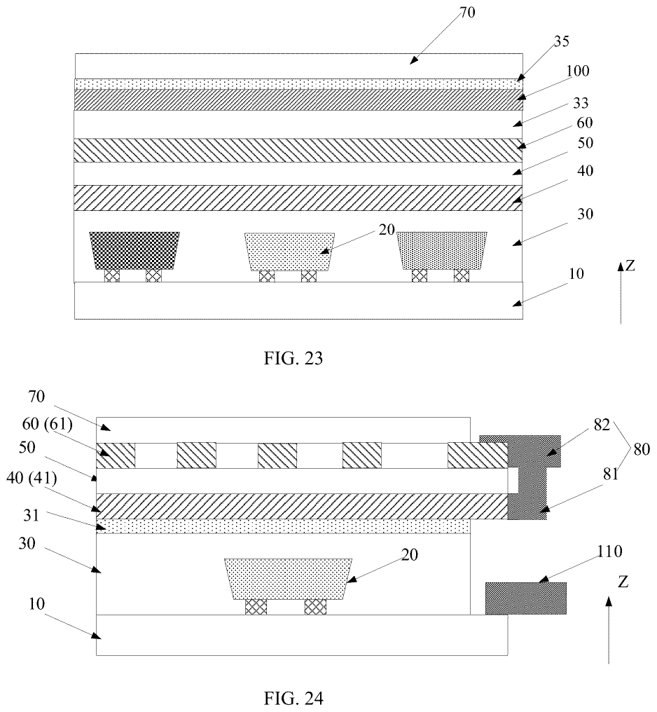

Based on any of the above embodiments, in one embodiment, as shown in FIG. 23, the touch display panel further includes a polarizer 100 located between the at least one touch electrode layer 60 and the protective cover 70. The polarizer 100 is configured to reduce the ambient light reflection on the display surface of the touch display panel and improve quality of a display screen of the touch display panel.

In the embodiment, if the first insulating layer 50 is an insulating substrate, when the at least one touch electrode layer 60 is formed on the insulating substrate and attached to the array substrate 10, optionally, before the insulating substrate is attached to the array substrate 10, the polarizer 100 is formed on a side of the sensing electrode away from the insulating substrate, and the polarizer 100 and the insulating substrate are integrally attached to the array substrate 10.

Optionally, in one embodiment, as shown in FIG. 23, a third flat layer 33 is also arranged between the protective cover 70 and the at least one touch electrode layer 60. The polarizer 100 is located on a side surface of the third flat layer 33 away from the array substrate 10. The protective cover 70 is fixed on the polarizer 100 through a second adhesive layer 35. Optionally, the second adhesive layer 35 is an optically transparent adhesive layer, which fixes the polarizer 100 and the protective cover 70 without affecting light emission of the LED 20.

In the above embodiments, the touch display panel may only include the polarizer 100 as an anti-reflective element or may include a combination of two anti-reflective elements: the polarizer 100 and the first anti-reflection structure 91, or a combination of the polarizer 100 and the second anti-reflection structure 92, which is not limited herein but depends on the anti-reflection requirements of the touch display panel.

Based on any of the above embodiments, in one embodiment, as shown in FIG. 24, the touch display panel further includes a touch circuit 80, for implementing touch detection based on at least one signal on the at least one touch electrode layer 60; and a display control circuit 110, for controlling working statuses of the plurality of LEDs 20.

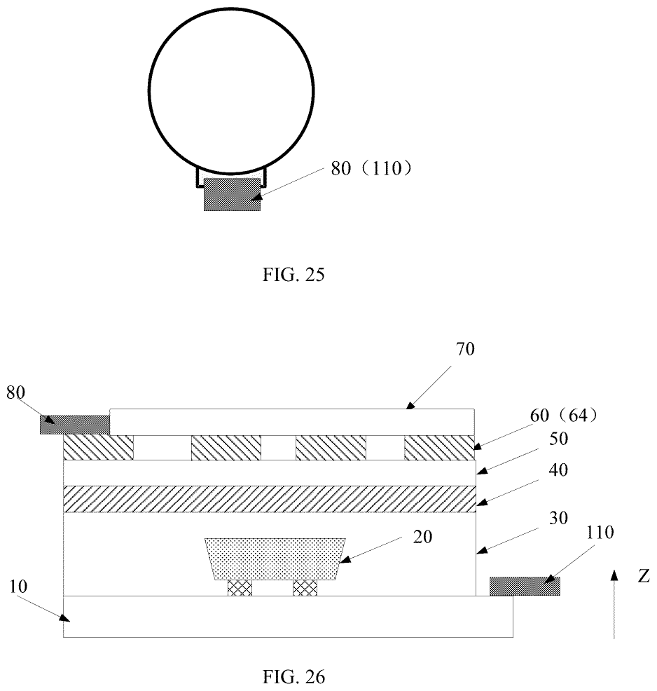

Optionally, in one embodiment, as shown in FIGS. 24 and 25, the touch circuit 80 and the display control circuit 110 are located on a same side of the display area of the touch display panel. In another embodiment, as shown in FIGS. 26-28, the touch circuit 80 and the display control circuit 110 are located on opposite sides of the display area of the touch display panel.

Although in FIGS. 25, 27 and 28, the display area of the touch display panel is illustrated by taking a circular display area as an example, which is not limited herein. In other embodiments, the display area of the touch display panel can also be in other shapes such as a rectangle or any other shape.

In the above embodiment, the display control circuit 110 and the touch circuit 80 are located on a same side of the display area of the touch display panel, making layouts of leads of the display control circuit 110 and the touch circuit 80 more convenient and structures of the display control circuit 110 and the touch circuit 80 simpler. However, superimposing the two circuits in a vertical direction will increase the structural strength of sides where the two circuits are placed and increase a bending radius, which is not conducive to achieving a narrow frame.

On the contrary, if the display control circuit 110 and the touch circuit 80 are located on different sides of the display area of the touch display panel, a structural strength of one side of the touch display panel will be smaller and the bending radius will decrease, which is conducive to achieving a narrow frame but is not conducive to layouts of the display control circuit and the touch circuit and makes structures of the display control circuit and the touch circuit more complicated.

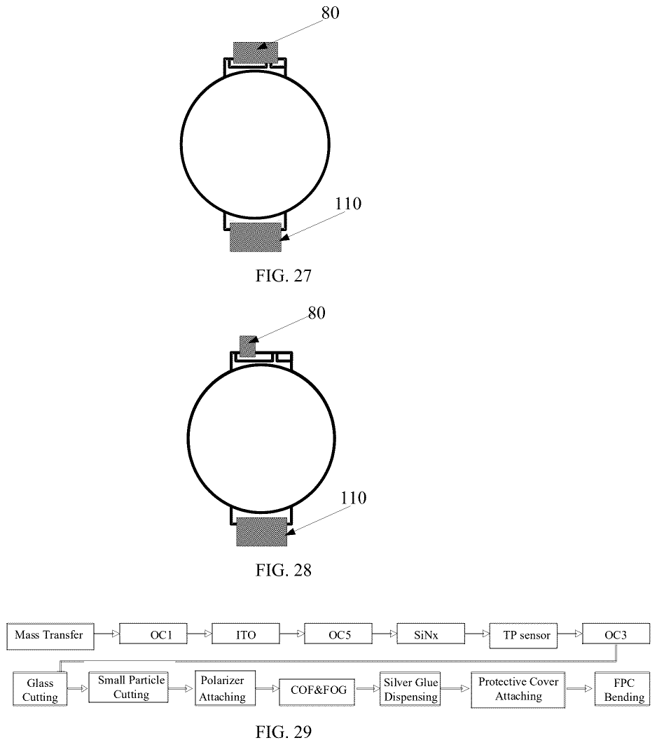

FIG. 27 illustrates a top view of the touch display panel when the ground electrode in the touch circuit 80 covers the through hole in the first insulating layer 50 in the direction Z perpendicular to the plane of the touch display panel. FIG. 28 illustrates a top view of the touch display panel when the ground electrode in the touch circuit 80 is away from the side of the touch electrode of the touch display panel.

Optionally, in one embodiment, when the touch circuit 80 and the display control circuit 110 are located on a same side of the display area of the touch display panel, the touch circuit 80 does not overlap the display control circuit 110 in the direction Z perpendicular to the plane of the array substrate, to avoid damaging an initially bonded circuit during a binding process of a subsequently bonded circuit.

As shown in FIG. 29, taking the at least one touch electrode layer 60 including the second touch electrode layer as an example, in one embodiment, a forming process of the touch display panel includes forming an array substrate structure. The array substrate structure includes a plurality of array substrates 10, with each array substrate 10 corresponding to one touch display panel. The plurality of LEDs 20 is transferred to the array substrate structure through mass transfer and bonded to the array substrate structure. A first flat layer (OC1) 30 covering the plurality of LEDs 20 is formed. A transparent electrode layer (ITO) is formed as a shielding layer 40 on a side of the first flat layer 30 away from the array substrate structure. A first insulating layer (including OC5 and SiNx) 50 is formed on a side of the shielding layer 40 away from the first flat layer 30. A second touch electrode layer (TP sensor) is formed on the side of the first insulating layer 50 away from the shielding layer 40. A third flat layer (OC3) 33 covering the second touch electrode layer is formed as a protective layer of the second touch electrode layer to obtain the structure to be divided. Glass cutting (i.e., G3.5 cutting) and small particle cutting processes are applied to divide the array substrate structure into a plurality of array substrates 10. A polarizer 100 is attached to the side of the third flat layer 33 away from the array substrate 10. The touch circuit 80 and the display control circuit 110 are bonded to the array substrate 10. Silver glue is dispensed through a glue dispensing process to realize an electrical connection between the ground electrode and the shielding layer in the touch circuit (silver glue). The protective cover 70 is attached. A circuit board of the touch circuit 80 and a circuit board of the display control circuit 110 are bent toward a side of the array substrates 10 away from the LED to complete a formation of the touch display panel.

G3.5 cutting refers to a cutting process of a 3.5-generation glass substrate during a display panel formation process. For example, a G3.5 generation glass substrate typically measures approximately 60 cm×72 cm. G3.5 cutting involves dividing the 60 cm×72 cm substrate into 10 cm×20 cm sections, while small grain cutting further trims the 10 cm∴20 cm sections into touch display panels of a target size.

In one embodiment, a purpose of the first insulating layer 50, which includes the fifth flat layer (OC5) and the silicon nitride layer (SiNx), is to provide a flat surface through the fifth flat layer, while the silicon nitride layer enhances water and oxygen isolation as well as electrical insulation, thereby reducing requirements for the fifth flat layer's water and oxygen isolation and electrical insulation properties.

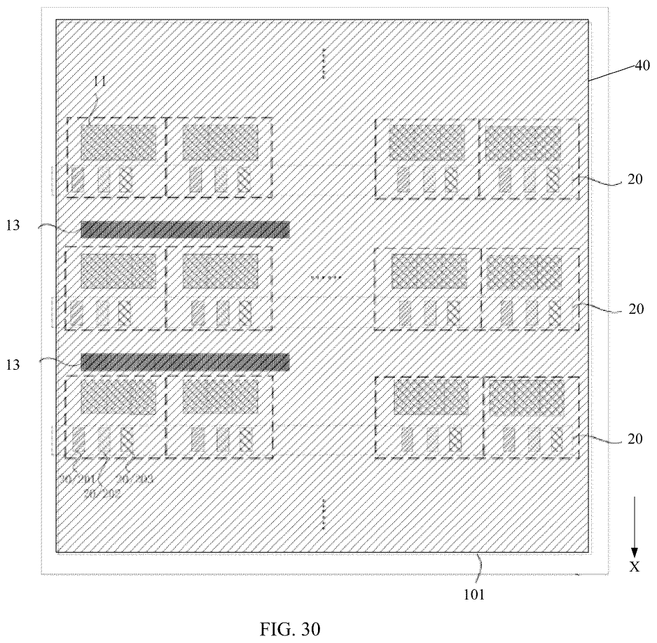

Based on any of the above embodiments, in one embodiment, as shown in FIG. 30, the array substrate 10 includes a pixel circuit 11 and a driving circuit 13. The driving circuit 13 is electrically connected to the pixel circuit 11 and is configured for transmitting a driving signal to the pixel circuit 11. The pixel circuit 11 is electrically connected to the LED 20 and is configured for driving an LED 20. Optionally, in one embodiment, in the direction Z perpendicular to the plane of the array substrate, the pixel circuit 11 and/or the driving circuit 13 are in the display area 101 of the touch display panel. That is, in the direction Z perpendicular to the plane of the array substrate, at least one of the pixel circuit 11 and the driving circuit 13 is in the display area 101 of the touch display panel to further reduce a size of the frame area of the touch display panel, and even achieve a borderless, full-screen design of the display panel for application in spliced display devices. Specifically, in one embodiment, as shown in FIG. 30, the plurality of LEDs 20 includes a first LED 201, a second LED 202 and a third LED 203. Colors of light emitted by the first LED 201, the second LED 202 and the third LED 203 are different. For example, the first LED 201 emits red light, the second LED 202 emits green light, and the third LED 203 emits blue light.

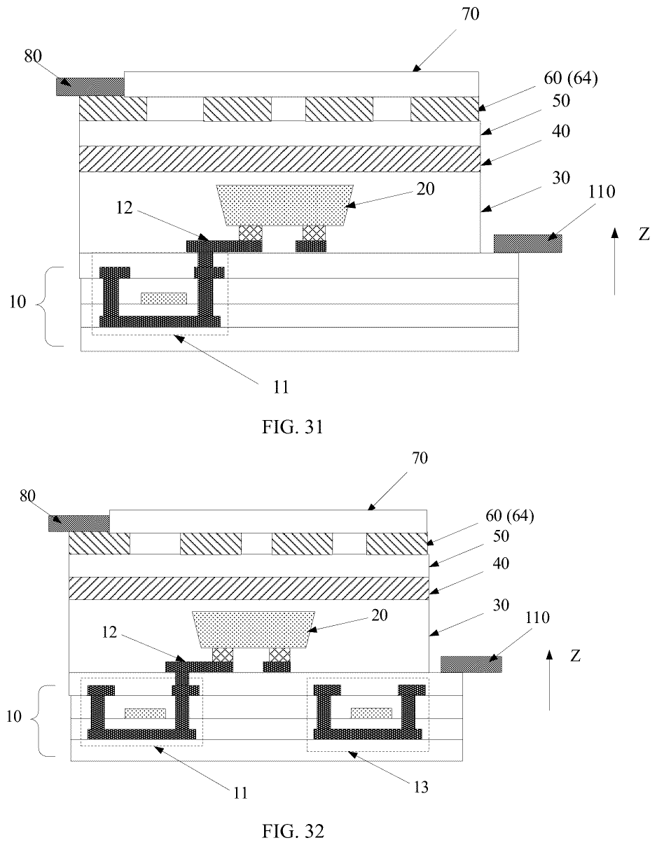

Optionally, based on the above embodiments, in one embodiment, as shown in FIGS. 30 and 31, in the direction Z perpendicular to the plane of the array substrate 10, the pixel circuit 11 does not overlap the LED 20 to prevent transistor damage in the pixel circuit 11 during a transfer and bonding of the LED 20 to the array substrate 10, thereby ensuring quality and yield of the display panel. In other embodiments, the pixel circuit 11 may also overlap the LED 20 in the direction Z perpendicular to the plane of the array substrate.

Optionally, in one embodiment, the LED 20 is bonded and connected to the array substrate 10 through the bonding layer 12.

Based on any of the above embodiments, in one embodiment, as shown in FIGS. 30 and 32, in the direction Z perpendicular to the plane of the array substrate, the driving circuit 13 does not overlap with the LED 20 to prevent transistor damage in driving circuit 13 during a transfer and bonding of the LED 20 to the array substrate 10, thereby ensuring the quality and yield of the display panel. In other embodiments, the driving circuit 13 may also overlap the LED 20 in the direction Z perpendicular to the plane of the array substrate.

Specifically, in one embodiment, the driving circuit 13 is a shift register circuit that includes a plurality of cascaded shift registers to provide a scanning signals to the pixel circuit, which is not limited herein. Optionally, in one embodiment, as shown in FIG. 30, along a first direction, driving circuits 13 and pixel circuits 11 are alternately arranged so that each driving circuit 13 is electrically connected to a corresponding pixel circuit 11, thereby providing a driving signal to the pixel circuit 11. The first direction X is parallel to the plane of the touch display panel. Optionally, the first direction is a column direction of the touch display panel. In other embodiments, the first direction X may also be a row direction of the touch display panel.

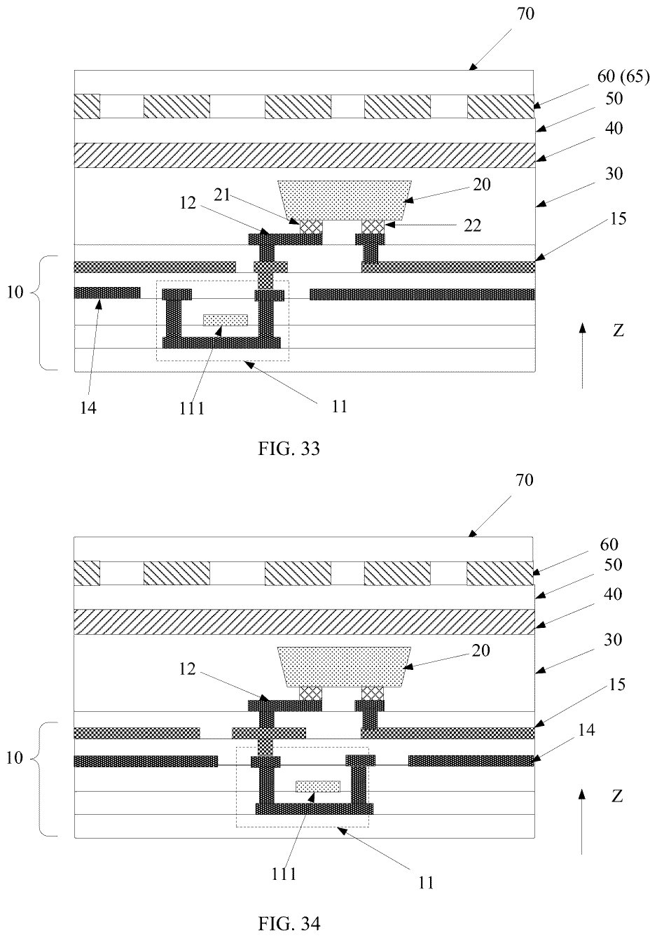

Based on any of the above embodiments, in one embodiment, as shown in FIG. 33, the touch display panel includes a first metal layer 14 and a second metal layer 15. The first metal layer 14 includes a first power supply structure, and the second metal layer 15 includes a second power supply structure. The first power supply structure is electrically connected to the pixel circuit 11, which is electrically connected to a first electrode 21 of the LED 20, and the second power supply structure is electrically connected to a second electrode 22 of the LED 20. During specific operation, the first power supply structure provides a first power signal to the first electrode 21 of the LED 20 through the pixel circuit 11, and the second power supply structure provides a second power signal to the second electrode 22 of the LED 20. Optionally, the first power signal is a PVDD signal, and the second power signal is a PVEE signal.

Based on the above embodiments, in one embodiment, as shown in FIG. 33, the array substrate 10 includes an active layer (i.e., the first active layer 111), the first metal layer 14 and the second metal layer 15 are located on a side of the active layer facing the LED 20. In the direction Z perpendicular to the plane of the array substrate 10, the first metal layer 14 and the second metal layer 15 cover at least part of the active layer to reduce damage to the active layer during a bonding process of the LED 20. Optionally, in the direction Z perpendicular to the plane of the array substrate 10, the first metal layer 14 and the second metal layer 15 may completely cover the active layer to further reduce damage to the active layer during the bonding process of the LED 20.

Specifically, in one embodiment, the active layer includes a first active layer and a second active layer. The first active layer includes an active layer of each transistor in the pixel circuit, and the second active layer includes an active layer of each transistor in the driver circuit.

As shown in FIG. 34, when the first metal layer 14 and the second metal layer 15 cover at least part of the first active layer 111, the pixel circuit 11 may also overlap the LED 20. Optionally, the first active layer 111 in an overlapping portion of the pixel circuit 11 and the LED 20 is covered by the first metal layer 14 and/or the second metal layer 15 to reduce the probability that the bonding process of the LED 20 causes damage to the first active layer 111 of the transistor in the pixel circuit 11. By arranging the pixel circuit 11 to overlap the LED 20, the distance between adjacent LEDs 20 is reduced, which is conducive to improving a resolution of the touch display panel.

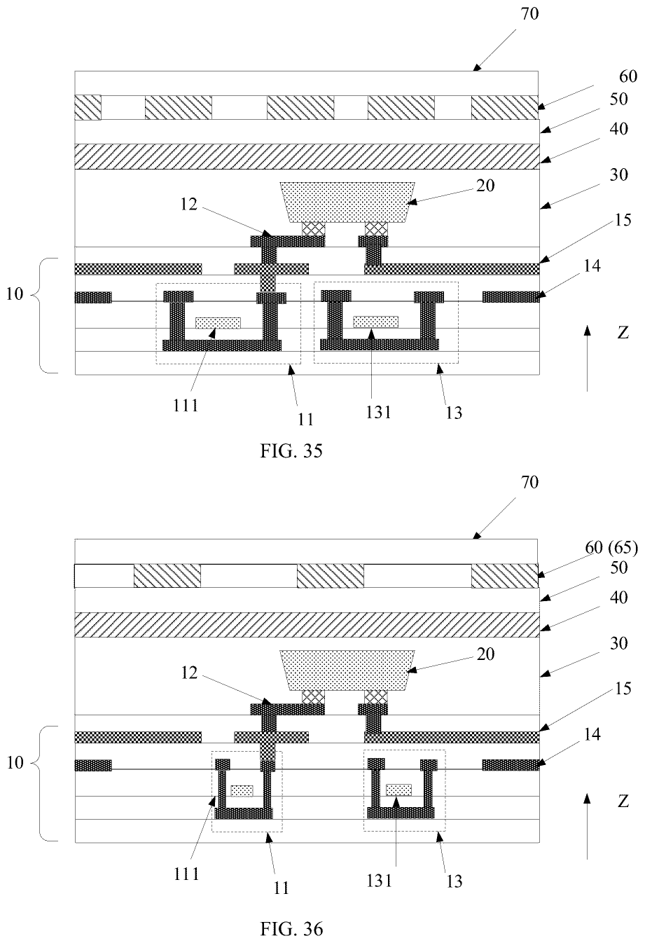

Similarly, as shown in FIG. 35, when the first metal layer 14 and the second metal layer 15 cover at least part of the second active layer 131, the driving circuit 13 may also overlap the LED 20. Optionally, the second active layer in an overlapping portion of the driving circuit 13 and the LED 20 is covered by the first metal layer and/or the second metal layer to reduce a probability that the bonding process of the LED 20 causes damage to the first active layer 111 of transistors in the pixel circuit 11. By arranging the driving circuit to overlap the LED, a distance between adjacent LEDs is reduced, which is conducive to improving a resolution of the touch display panel.

Optionally, in one embodiment, as shown in FIGS. 33 and 34, in the direction Z perpendicular to the plane of the array substrate 10, the first metal layer 14 and the second metal layer 15 are located between the pixel circuit 11 and the LED 20, and between the driving circuit 13 and the LED 20. In addition to protecting the active layers in the driving circuit 13 and the pixel circuit 11, the first and second metal layers 14 and 15 also serve to shield signals in the driving circuit 13 and the pixel circuit 11, thereby reducing interference of the signals in the driving circuit 13 and the pixel circuit 11 with the at least one touch electrode layer 60 and improving touch detection accuracy.

Optionally, in one embodiment, in the direction Z perpendicular to the plane of the array substrate, the first metal layer 14 and the second metal layer 15 cover the pixel circuit 11 and the driving circuit 13. In addition to protecting the active layers in the driving circuit 13 and the pixel circuit 11, the first and second metal layers 14 and 15 also serve to shield signals in the driving circuit 13 and the pixel circuit 11, thereby further reducing interference of the signals in the driving circuit 13 and the pixel circuit 11 to the at least one touch electrode layer 60 and further improving touch detection accuracy.

Based on any of the above embodiments, in one embodiment, as shown in FIG. 36, the at least one touch electrode layer 60 includes a plurality of touch electrodes 65. In the direction Z perpendicular to the plane of the array substrate 10, at least part of the touch electrodes 65 do not overlap the pixel circuit 11, thereby reducing interference of a signal in the pixel circuit 11 with the touch electrodes 65 and improving the touch detection accuracy of the touch display panel. Optionally, as shown in FIG. 36, in the direction Z perpendicular to the plane of the array substrate, the plurality of touch electrodes 65 does not overlap the pixel circuit 11, further reducing interference of signals from the pixel circuit 11 with the touch electrodes and improving touch detection accuracy.

Similarly, as shown in FIG. 36, in the direction Z perpendicular to the plane of the array substrate, at least part of the touch electrode 65 does not overlap the driving circuit 13, so that at least part of the touch electrodes 65 does not overlap the driving circuit 13, thereby reducing interference of a signal in the driving circuit 13 with the touch electrodes 65 and improving touch detection accuracy of the touch display panel. Optionally, in the direction Z perpendicular to the plane of the array substrate, as shown in FIG. 36, the plurality of touch electrodes 65 does not overlap the driving circuit 13, further reducing interference of a signal in the driving circuit 13 with the touch electrodes and improving touch detection accuracy.

Optionally, in one embodiment, in the direction Z perpendicular to the plane of the array substrate, at least part of the touch electrode 65 does not overlap the pixel circuit 11 and the driving circuit 13, thereby reducing interference of signals in the pixel circuit 11 and the driving circuit 13 with the touch electrodes 65, and improving touch detection accuracy.

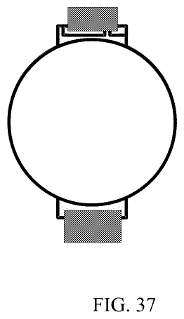

As shown in FIG. 37, a touch display device is provided in one embodiment, which includes the touch display panel provided in any of the above embodiments. Optionally, the touch display device can be a mobile phone, tablet computer, wearable device, vehicle-mounted device, augmented reality (AR)/virtual reality (VR) device, notebook computer, ultra-mobile personal computer (UMPC), netbook, personal digital assistant (PDA), or the like, which is not limited herein.

As disclosed, the touch display panel and the touch display device provided by the present disclosure at least realize the following beneficial effects.

The touch display panel not only includes a plurality of LEDs for display but also includes at least one touch electrode layer to implement touch, so that the touch function is integrated into the LED display panel. In the touch display panel, the at least one touch electrode layer is located between the protective cover and the shielding layer. In other words, the at least one touch electrode layer is integrated within the touch display panel. By integrating the touch function into the LED display panel, the overall thickness of the touch display panel is reduced, which is conducive to a development of a lightweight and slim touch display panel. In addition, in the touch display panel, a shielding layer is arranged between the at least one touch electrode layer and the plurality of LEDs, so that the shielding layer can be used to shield interference from driving signals of the LEDs on the at least one touch electrode layer, thereby improving touch detection accuracy of the touch display panel.

Each embodiment in the present specification is described either progressively, in parallel, or as a combination of progression and parallelism. Each embodiment focuses on differences from other embodiments, and same or similar parts across embodiments can be referred to each other. For the device disclosed in one embodiment, since the device corresponds to the method disclosed in the embodiments, a description of the device is relatively simple, and relevant details can be found in a description of the method.

In the description of the present disclosure, it is understood that the accompanying drawings and description of the embodiments are illustrative rather than restrictive. Same reference numerals identify same structures throughout the description of the embodiments. In the present specification, relational terms such as “first”,“ second”, and the like are used to distinguish one entity or operation from another entity or operation and do not necessarily require or imply an existence of any such actual relationship or order between the entities or operations. Furthermore, terms “comprises,” “includes,” or any other variation thereof are intended to cover a non-exclusive inclusion, such that an article or device including a list of elements includes not only those elements, but also other elements not expressly listed, or elements inherent to the article or device. Without more limitations, an element defined by a phrase “comprises a . . . ” does not exclude a presence of additional same elements in the article or device including the above elements.

The above description of the disclosed embodiments enables a person skilled in the art to implement or use the present disclosure. Various modifications to the embodiments will be apparent to a person skilled in the art. General principles defined herein may be applied to other embodiments without departing from the spirit or scope of the present disclosure. Therefore, the present disclosure is not to be limited to the embodiments described herein but is to be accorded the broadest scope consistent with principles and novel features disclosed herein.

1. A touch display panel, comprising:
an array substrate;
a plurality of LEDs on a side of the array substrate;
a first flat layer covering the plurality of LEDs;
a shielding layer on a side of the first flat layer away from the array substrate;
a first insulating layer on a side of the shielding layer away from the first flat layer;
at least one touch electrode layer on a side of the first insulating layer away from the shielding layer; and
a protective cover on a side of the at least one touch electrode layer away from the first flat layer,
wherein the shielding layer is a planar transparent conductive layer, and wherein, in a direction perpendicular to a plane of the touch display panel, the shielding layer at least covers a wiring electrically connected to the plurality of LEDs.

2. The touch display panel according to claim 1, wherein the shielding layer includes a plurality of first electrodes, the at least one touch electrode layer includes a first touch electrode layer, the first touch electrode layer includes a plurality of second electrodes, the first electrodes are driving electrodes, and the second electrodes are sensing electrodes.

3. The touch display panel according to claim 2, wherein:
the first insulating layer is an insulating substrate, and the shielding layer is bonded to the first flat layer through a first adhesive layer; or
the first insulating layer is a flat layer, and a second flat layer is arranged between the shielding layer and the first flat layer.

4. The touch display panel according to claim 2, further comprising a touch circuit, wherein the touch circuit includes:
a first touch circuit bonded to a side of the first insulating layer facing the first flat layer and a second touch circuit bonded to a side of the first insulating layer facing the protective cover.

5. The touch display panel according to claim 1, wherein the at least one touch electrode layer includes a second touch electrode layer, which includes a plurality of block electrodes, and the shielding layer overlaps the plurality of block electrodes in a direction perpendicular to a plane of the touch display panel.

6. The touch display panel according to claim 5, further comprising a touch circuit bonded to a side of the first insulating layer facing the protective cover.

7. The touch display panel according to claim 6, wherein the first insulating layer includes a through hole, and the shielding layer is electrically connected to a ground electrode in the touch circuit through the through hole.

8. The touch display panel according to claim 7, wherein:
the ground electrode covers the through hole in the direction perpendicular to the plane of the touch display panel; or the through hole is located on a side of the ground electrode away from a touch electrode of the touch display panel in the direction perpendicular to the plane of the touch display panel.

9. The touch display panel according to claim 1, wherein a thickness h0 of the first flat layer and a thickness h1 of the LED satisfy a following relationship: h1≤h0≤2*h1 in a direction perpendicular to the plane of the touch display panel.

10. The touch display panel according to claim 1, further comprising an anti-reflection structure between the array substrate and the protective cover, wherein:
the anti-reflection structure includes at least one of a first anti-reflection structure and a second anti-reflection structure, the first anti-reflection structure includes a plurality of color resistance units, which cover the plurality of LEDs in a direction perpendicular to the plane of the array substrate; and
the second anti-reflection structure includes light-absorbing layers, and at least part of the light-absorbing layer is located in regions between adjacent LEDs.

11. The touch display panel according to claim 10, wherein:
the first anti-reflection structure is located between the at least one touch electrode layer and the protective cover; or
the first anti-reflection structure is located between the first flat layer and the shielding layer; or
the second anti-reflection structure is located on a same layer as the plurality of LEDs; or
the second anti-reflection structure is located between the first flat layer and the shielding layer.

12. The touch display panel according to claim 10, wherein the anti-reflection structure includes a first anti-reflection structure and a second anti-reflection structure, and the first anti-reflection structure and the second anti-reflection structure are located on a same layer.

13. The touch display panel according to claim 12, wherein the first anti-reflection structure and the second anti-reflection structure are located between the first flat layer and the shielding layer.

14. The touch display panel according to claim 1, further comprising a polarizer between the at least one touch electrode layer and the protective cover.

15. The touch display panel according to claim 1, further comprising:
a touch circuit, for implementing touch detection based on at least one signal on the at least one touch electrode layer;
a display control circuit, for controlling working statuses of the plurality of LEDs; and
the touch circuit and the display control circuit being located on opposite sides of a display area of the touch display panel.

16. The touch display panel according to claim 1, wherein:
the array substrate includes a pixel circuit and a driving circuit; and
the driving circuit is configured for transmitting a drive signal to the pixel circuit, and the pixel circuit is configured for driving an LED of the plurality of LEDs, and the pixel circuit and/or the driving circuit is in a display area of the touch display panel in a direction perpendicular to a plane of the array substrate.

17. The touch display panel according to claim 16, wherein:
the pixel circuit and/or the driving circuit do not overlap the LED in the direction perpendicular to the plane of the array substrate; or
the pixel circuit and/or the driving circuit overlap the LED in the direction perpendicular to the plane of the array substrate.

18. The touch display panel according to claim 17, further comprising a first metal layer and a second metal layer, wherein:
the first metal layer includes a first power supply structure, the second metal layer includes a second power supply structure, the first power supply structure is electrically connected to the pixel circuit, the pixel circuit is electrically connected to a first electrode of the LED, and the second power supply structure is electrically connected to a second electrode of the LED; and
the array substrate includes an active layer, the first metal layer and the second metal layer are located on a side of the active layer facing the LED, in the direction perpendicular to the plane of the array substrate, the first metal layer and the second metal layer at least partially cover the active layer;
in the direction perpendicular to the plane of the array substrate, the first metal layer and the second metal layer are located between the pixel circuit and the LED, and between the driving circuit and the LED; and
in the direction perpendicular to the plane of the array substrate, the first metal layer and the second metal layer cover the pixel circuit and the driving circuit.

19. The touch display panel according to claim 16, wherein the at least one touch electrode layer includes a plurality of touch electrodes, in a direction perpendicular to the plane of the array substrate, at least part of the plurality of touch electrodes does not overlap either the pixel circuit or the driving circuit.

20. A touch display device comprising a touch display panel comprising:
an array substrate;
a plurality of LEDs on a side of the array substrate;
a first flat layer covering the plurality of LEDs;
a shielding layer on a side of the first flat layer away from the array substrate;
a first insulating layer on a side of the shielding layer away from the first flat layer;
at least one touch electrode layer on a side of the first insulating layer away from the shielding layer; and
a protective cover on a side of the at least one touch electrode layer away from the first flat layer,
wherein the shielding layer is a planar transparent conductive layer, and wherein, in a direction perpendicular to a plane of the touch display panel, the shielding layer at least covers a wiring electrically connected to the plurality of LEDs.
